(19) United States
(12) Patent Application Publication
(10) Pub. No.: US 2023/0343581 A1
(43) Pub. Date: Oct. 26, 2023

(54) INHERENT AREA SELECTIVE DEPOSITION OF MIXED OXIDE DIELECTRIC FILM

(71) Applicant: Gelest, Inc., Morrisville, PA (US)

(72) Inventor: Chad Michael BRICK, Yardley, PA (US)

(21) Appl. No.: 18/137,128

(22) Filed: Apr. 20, 2023

Related U.S. Application Data
(60) Provisional application No. 63/333,276, filed on Apr. 21, 2022.

(51) Int. Cl. H01L 21/02; C01B 33/20; C23C 16/455; C23C 16/02; C23C 16/56; C23C 16/04; C23C 16/40

(52) U.S. Cl. CPC H01L 21/02164; C01B 33/20; C23C 16/45527; C23C 16/0227; C23C 16/56; C23C 16/042; C23C 16/45553; C23C 16/402; H01L 21/0228; C01P 2006/40

(57) ABSTRACT

The disclosure relates to the inherently selective mixed oxide deposition of a dielectric film on non-metallic substrates without concomitant growth on metallic substrates using a sequence of exposure to metal alkyl, heteroatom silacyclic compound, and water. The resulting films show much higher growth rates than corresponding metal oxide and inherent selectivity towards non-metallic surfaces. Films as thick as 14 nm can be grown on dielectric substrates such as thermal oxide and silicon nitride without any growth observed on metallic films such as copper and without the use of an inhibitor. Such dielectric-on-dielectric (DoD) growth is a critical element of many proposed fabrication schemes for future semiconductor device fabrication such as fully self-aligned vias.

### CROSS-REFERENCE TO RELATED APPLICATION

This application claims priority to U.S. provisional patent application No. 63/333,276, filed Apr. 21, 2022, the disclosure of which is herein incorporated by reference in its entirety.

### BACKGROUND OF THE INVENTION

Reductions in feature size have long been a driving force for improvements in semiconductor manufacturing technology. However, aligning photolithographic masks with existing features on a substrate has become a major impediment to reducing the feature sizes even further. The edge placement errors that result from mask misalignment can result in immediate or time-dependent dielectric breakdown, causing reduced yield or declines in device reliability, respectively. To address the problem of edge placement error, a strategy called fully self-aligned vias (FSAV) has been developed. This technique involves selectively growing a dielectric film on the existing dielectric layer without growing on the metal lines using an area selective deposition (ASD) process. The topographical height step created by the grown dielectric layer allows greater tolerance for misalignment during the subsequent via etch steps by increasing the distance between the vias and adjacent metal lines.

ASD refers to the selective deposition of a material on target (growth) regions of a substrate without growth of the target material on other regions of the substrate (non-growth). Most successful and proposed ASD processes use a combination of atomic layer deposition, where the growth is highly precise and the initiation rate can be manipulated by control of surface chemistry, and selective blocking functionalities on the non-growth surface. However, the use of blocking groups on some or all of the non-growth surfaces generally requires two extra process steps, one to add and one to remove the blocking groups. Inherently selective processes, which do not require the extra process steps to add and remove blocking agents, are desirable not only because of the reduction in the number of steps of the manufacturing process, but also because as critical dimensions shrink even further and the topological complexity of the substrates increase, the ability to introduce and remove the required chemical blocking agents into the nanometer-scale features can become physically constrained.

### SUMMARY OF THE INVENTION

In one embodiment, the disclosure relates to a method for forming a mixed oxide dielectric film on a patterned substrate, the method comprising:
(a) introducing a patterned substrate having metallic and non-metallic regions into a reaction zone of a deposition chamber and heating the reaction zone to about 175° C. to about 350° C.;
(b) exposing the patterned substrate to a pulse of a metal alkyl compound;
(c) purging the deposition chamber;
(d) exposing the patterned substrate to a pulse of a heteroatom silacyclic compound;
(e) purging the deposition chamber;
(f) exposing the patterned substrate to a pulse of water;
(g) purging the deposition chamber; and
(h) repeating steps (b) to (g) until a desired mixed oxide dielectric film thickness is achieved.

In a second embodiment, aspects of the disclosure relate to a method for forming a mixed oxide dielectric film on a patterned substrate, the method comprising:
(a) introducing a patterned substrate having metallic and non-metallic regions into a reaction zone of a deposition chamber and heating the reaction zone to about 175° C. to about 350° C.;
(b) exposing the patterned substrate to a pulse of a metal alkyl compound;
(c) purging the deposition chamber;
(d) exposing the patterned substrate to a pulse of a heteroatom silacyclic compound;
(e) purging the deposition chamber;
(f) exposing the substrate to a pulse of water;
(g) purging the deposition chamber; and
(h) repeating steps (b) to (g) at least one time;
(i) performing a plasma treatment step; and
(j) repeating steps (b) to (i) until a desired mixed oxide dielectric film thickness is achieved.

### BRIEF DESCRIPTION OF THE SEVERAL VIEWS OF THE DRAWINGS

The following detailed description of preferred embodiments of the present invention will be better understood when read in conjunction with the appended drawings. For the purposes of illustrating the invention, there is shown in the drawing an embodiment which is presently preferred. It is understood, however, that the invention is not limited to the precise arrangements and instrumentalities shown. In the drawings:

FIG. 1 is a graph of thickness v. time for the films of Examples 1 and 2 and Comparative Examples 1 and 2; and

FIG. 2 is a graph of thickness v. time for the films of Examples 3, 4, and 5.

### DETAILED DESCRIPTION OF THE INVENTION

Aspects of the disclosure relate to a method for the area selective mixed oxide deposition of a dielectric film on the non-metallic area of a substrate without concomitant growth on a metallic area of the substrate using a facile sequence of exposure to a metal alkyl compound, cyclic azasilane compound, and water. The resulting films show much higher growth rates than corresponding metal oxide and high selectivity towards non-metallic surfaces. Films as thick as 15 nm can be grown on dielectric substrates, such as thermal oxide and silicon nitride, without any growth observed on metallic films such as copper. Such dielectric-on-dielectric (DoD) growth is a critical element of many proposed fabrication schemes for future semiconductor device fabrication such as fully self-aligned vias.

The method according to the disclosure involves introducing a patterned substrate having metallic and non-metallic regions into a reaction zone of a deposition chamber and exposing the patterned substrate to the following sequence of steps which are repeated as many times as necessary to achieve the desired film thickness: exposing the patterned substrate to a pulse of a metal alkyl compound, purging the deposition chamber, exposing the patterned substrate to a pulse of a heteroatom silacyclic compound, purging the deposition chamber, exposing the substrate to a pulse of deionized water, and purging the deposition chamber. The resulting mixed oxide dielectric layer selectively forms on non-metallic regions or areas of the patterned substrate. For the purposes of this disclosure, the terms “layer” and “film” may be understood to be synonymous.

Optionally, prior to exposing the patterned substrate to a pulse of a metal alkyl compound, the patterned substrate is exposed to a chemical compound that inhibits growth on some or all of the metallic regions. If such an optional step is performed, the inhibitor compound may be removed once the desired dielectric film thickness has been achieved. Inhibitor compounds that may be used include, without limitation, organic or organosilane thiols, amines, aldehydes, and phosphonic acids, which may be removed by dry processes not limited to plasma etching, reactive ion etching, corona treatment, ozonolysis, UV/ozone, thermal decomposition or thermal desorption, or wet etching processes utilizing formulations comprising organic solvents, acid, base, or hydrogen peroxide.

In some embodiments, prior to exposing the substrate to the metal alkyl compound, it is within the scope of the disclosure to pretreat the substrate. The pretreatment may be accomplished by chemical, structural, or plasma (particularly non-oxidizing plasma) pretreatment methods which are well known in the art. For example, the substrate may be pretreated by washing in ethanol, isopropanol, citric acid, or acetic acid-based formulations, or by exposing the substrate to 60 seconds of 5% H₂/95% N₂ remote inductively coupled plasma at 2500 W at 225 to 250° C. Other similar substrate pre-treatment processes which are known in the art would also be applicable. Such treatments may improve performance of the resulting films, but the appropriate pretreatment method and conditions may be determined on a case-to-case basis depending on the specific substrate, apparatus, reactants, and reaction conditions.

In some embodiments, after a number of exposure/purge sequences (such as about 1 to about 50 sequences) have been completed, the substrate is subjected to a pulse of a plasma treatment, such as for about 10 seconds. For example, a sequence of five exposure/pulse sequences may be performed prior to performing the plasma treatment. This sequence of five (for example) exposure/pulse sequences followed by a plasma pulse may be referred to as a “super cycle.” Such a super cycle may then be repeated as many times as required to form a film having the desired thickness. In some embodiments, it is also within the scope of the disclosure to perform a plasma treatment step before or after any of the exposure or purging steps.

It is within the scope of the disclosure to prepare mixed oxide dielectric films having thicknesses of 5 to 15 nm, particularly 7 nm to 10 nm, which thicknesses are currently desirable in the microelectronic industry, and further to prepare mixed oxide dielectric films having thicknesses of up to about 50 nm. For the purposes of this disclosure, the term “mixed oxide dielectric film” shall be understood to describe films comprising silicon, oxygen, and at least one metallic element selected from transition metals, lanthanides, Group 13 elements, Ge, Sn, Pb, As, Sb, and Bi, with the metallic element determined by the specific metal alkyl compound employed. The desired film or layer thickness may be achieved by repeating the method steps described herein repeatedly.

A variety of metal alkyl compounds may be employed in the method described herein, including, without limitation, Group 12 and Group 13 metal alkyl compounds. Exemplary metal alkyl compounds which may be employed include the presently preferred diethylzinc, trimethylaluminum, and dimethylaluminum isopropoxide, as well as dimethylzinc, trimethylgallium, triethylgallium, triethylaluminum, trimethylindium, dimethylcadmium, and dimethylmercury.

The heteroatom silacyclic compound used in the methods described herein may be, for example, a cyclic azasilane, cyclic tellurasilane, or cyclic thiasilane compound.

Appropriate cyclic azasilanes have general formula (1):

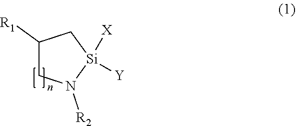

In formula (1), R₁ is hydrogen or a linear, branched, or cyclic, optionally substituted, alkyl, aryl, alkynyl, alkenyl, alkoxy, silyl, or alkylamino group having 1 to about 12 carbon atoms (preferably 1 to about 4 carbon atoms), R₂ is a linear, branched, or cyclic, optionally substituted, alkyl, aryl, alkynyl, alkenyl, alkoxy, silyl, or alkylamino group having 1 to about 12 carbon atoms (preferably 1 to about 4 carbon atoms), n is an integer of 1 to about 4, and X and Y are each independently a linear, branched, or cyclic, optionally substituted, alkyl, aryl, alkynyl, alkenyl, alkoxy, silyl, or alkylamino group (preferably about 1 to about 4 carbon atoms). It is within the scope of the disclosure for R₁, R₂, X, and Y to be unsubstituted or substituted with groups such as, without limitation, alkyl (such as methyl, ethyl, or propyl), alkoxysilyl (such as trimethoxysilyl or triethoxysilyl), alkoxy (such as methoxy or alkoxy), and/or halogen (such as chloro, bromo, fluoro, or iodo).

Exemplary R₁, R₂, X, and Y substituents include, without limitation, hydrogen, methyl, ethyl, n-propyl, i-propyl, n-butyl, s-butyl, t-butyl, pentyl, hexyl, phenyl, cyclohexyl, heptyl, n-octyl, 2-ethylhexyl, nonyl, decyl, dodecyl, octadecyl, methoxy, ethoxy, n-propoxy, i-propoxy, n-butoxy, s-butoxy, t-butoxy, vinyl, allyl, norbornenyl, methylnorbornenyl, ethylnorbornenyl, propylnorbornenyl, trimethylsilyl, trimethoxysilyl, methyl(trimethoxysilyl), ethyl(trimethoxysilyl), propyl(trimethoxysilyl), triethoxysilyl, methyl(triethoxysilyl), ethyl(triethoxysilyl), propyl(triethoxysilyl), amino, methyl amino, ethylamino, propylamino, methyl(dimethylamino), ethyl(dimethylamino), propyl(dimethylamino), and chloromethyl.

Preferably, R₁ is hydrogen or an alkyl group such as methyl or ethyl, R₂ is an optionally substituted alkyl, alkenyl, or alkylamino group having 1 to about 4 carbon atoms, such as 1, 2, 3, or 4 carbon atoms, and X and Y are preferably alkyl or alkoxy groups having 1 to about 4 carbon atoms, such as 1, 2, 3, or 4 carbon atoms.

Exemplary cyclic azasilane compounds which would be effective for forming a blocking layer on the patterned substrate include, without limitation, (N-methyl-aza-2,2,4-trimethyl silacyclopentane, N-(2-aminoethyl)-2,2,4-trimethyl-1-aza-silacyclopentane, N-n-butyl-aza-2,2-dimethoxysilacyclopentane, N-ethyl-2,2-dimethoxy-4-methyl-1-aza-2-silacyclopentane, (N,N-dimethylaminopropyl)-aza-2-methyl-2-methoxysilacyclopentane, (1-(3-triethoxysilyl)propyl)-2,2-diethoxy-1-aza-silacyclopentane, N-allyl-aza-2,2-dimethoxysilacyclopentane, and N-t-butyl-aza-2,2-diemethoxysilacyclopentane, and have the following structures:

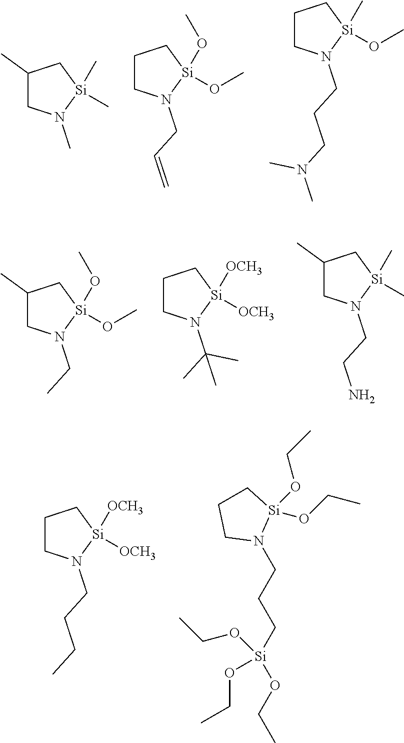

Appropriate cyclic thiasilanes have general formula (2):

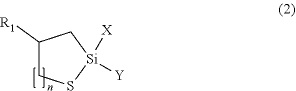

In formula (2), R₁, n, X, and Y are as described above. Preferably, R₁ is hydrogen or an alkyl group such as methyl or ethyl, and X and Y are preferably alkyl or alkoxy groups having 1 to about 4 carbon atoms, such as 1, 2, 3, or 4 carbon atoms.

An exemplary cyclic thiasilane compound which would be effective for forming a mixed oxide dielectric layer on the patterned substrate is 2,2,4-trimethyl-1-thia-2-silacyclopentane and has the following structure:

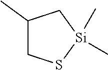

Appropriate cyclic tellurasilanes have general formula (3):

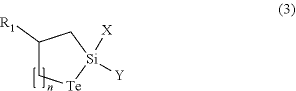

In formula (3), R₁, n, X, and Y are as described above. Preferably, R₁ is hydrogen or an alkyl group such as methyl or ethyl, and X and Y are preferably alkyl or alkoxy groups having 1 to about 4 carbon atoms, such as 1, 2, 3, or 4 carbon atoms. An exemplary cyclic tellurasilane compound which would be effective for forming a mixed oxide dielectric layer on the patterned substrate is 2,2,4-trim ethyl-1-tellura-2-silacyclopentane and has the following structure:

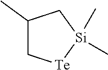

The presently preferred compounds for use in the methods described herein are cyclic azasilanes, and in particular N-methyl-aza-2,2,4-trimethylsilacyclopentane is the preferred compound:

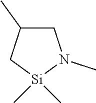

The parameters of the purge cycles are not particularly limited, and may be optimized based on the specific reaction conditions, apparatus, and reactants. Generally, any inert gas such as argon or nitrogen may be employed; typical purge cycles are at least about 2 seconds long. In preferred embodiments, the purges are about 5 seconds.

The temperatures of the substrate and the reaction zone of the deposition chamber are critical for producing the desired selective mixed oxide deposition on the patterned substrate. Specifically, the temperatures of the substrate and of the reaction zone in the deposition chamber during exposure to the pulses of the heteroatom silacyclic compound, the metal alkyl compound, and the water are preferably about 200° C. to about 300° C., more preferably about 225° C. to about 275° C. It may be understood that the ranges of substrate temperatures are inclusive of all temperatures within the range, so that temperatures of about 200° C. to about 300° C. include temperatures such as about 200° C., about 225° C., about 250° C., about 275° C., about 300° C., and all temperatures in between.

The pulse lengths of each reactant may also be optimized based on the specific reaction conditions and apparatus and are generally kept as short as practical. The pulse length for the metal alkyl compound is about 0.1 to about 10 seconds, preferably at least 0.3 seconds and more preferably about 0.3 seconds to about 0.7 seconds. The pulse length for the water pulses is about 0.1 to about 10 seconds, preferably about 1 to about 3 seconds. The pulse length for the heteroatom silacyclic compounds is about 0.1 to about 10 seconds, preferably about 1 to 5 seconds. While longer pulse times may be effective for all compounds, they are not practical from a materials consumption or tool utilization standpoint.

It is within the scope of the disclosure to move the reactants, such as the heteroatom silacyclic compound and metal alkyl compound, in a carrier gas. Without limitation, any noble gas, such as argon, or inert gas, such as nitrogen, would be appropriate. However, it is also within the scope of the disclosure not to employ a carrier gas.

A variety of different types of patterned substrates are appropriate for use in the method described herein, provided that they contain metallic and non-metallic regions. Appropriate substrates include, without limitation, the presently preferred silicon dioxide, silicon nitride, and copper on silicon. Other possible substrates which would be appropriate include, without limitation, substrates containing non-metallic regions comprising silicon, germanium, silicon-germanium alloy, silicon dioxide, silicon nitride, silicon oxycarbide, titanium nitride, tantalum nitride, silicon oxynitride, silicon carboxynitride, aluminum oxide, hafnium dioxide, titanium dioxide, and/or zinc oxide, and substrates containing metallic regions comprising copper, cobalt, tungsten, ruthenium, and/or molybdenum.

The invention will now be described in connection with the following, non-limiting examples.

### Example 1

A mixed oxide film was grown on thermally-grown silicon dioxide cleaned with 60 seconds of 5% H₂/95% N₂ remote inductively coupled plasma (2500 W) at 250° C. using an alternating pulse sequence of 0.5 seconds diethyl zinc, 5 second purge, 5.0 seconds N-methyl-aza-2,2,4-trimethylsilacyclopentane, 5 second purge, 2.0 seconds water, and 5 second purge, repeated 75 times. Film growth was slight for the first twenty cycles (<1 angstrom per cycle), after which growth initiated and quickly rose to 10.8 nm per cycle. Film thickness after the 43^{rd} cycle was 15.8 nm and the film refractive index was 1.48.

### Example 2

PVD copper on silicon was cleaned by sonication for five minutes in ethanol. A mixed oxide film was grown on the cleaned copper by exposing it to 60 seconds of 5% H₂/95% N₂ remote inductively coupled plasma (2500 W) at 250° C. and then subjecting it to an alternating pulse sequence of 0.5 seconds diethyl zinc, 5 second purge, 5.0 seconds N-methyl-aza-2,2,4-trimethylsilacyclopentane, 5 second purge, 2.0 seconds water, and 5 second purge, repeated 75 times. Initial film growth was observed on the 43^{rd} cycle and the growth rate still increasing at the final cycle.

### Comparative Example 1

Zinc oxide was grown on thermally-grown silicon dioxide cleaned with 60 seconds of 5% H₂/95% N₂ remote inductively coupled plasma (2500 W) at 250° C. using an alternating pulse sequence of 0.5 seconds diethyl zinc, 15 second purge, 2.0 seconds water, and 5 second purge, repeated 75 times. Film growth was immediate at 3.3 angstroms per cycle. The thickness of the film after nine cycles was 2.9 nm.

### Comparative Example 2

PVD copper on silicon was cleaned by washing for five minutes in ethanol. Zinc oxide was grown on the cleaned copper by exposing it to 60 seconds of 5% H₂/95% N₂ remote inductively coupled plasma (2500 W) at 250° C. and then subjecting it to an alternating pulse sequence of 0.5 seconds diethyl zinc, 15 second purge, 2.0 seconds water, and 5 second purge, repeated 75 times. Film growth was observed on the ninth cycle and stabilized at 4.1 angstroms per cycle

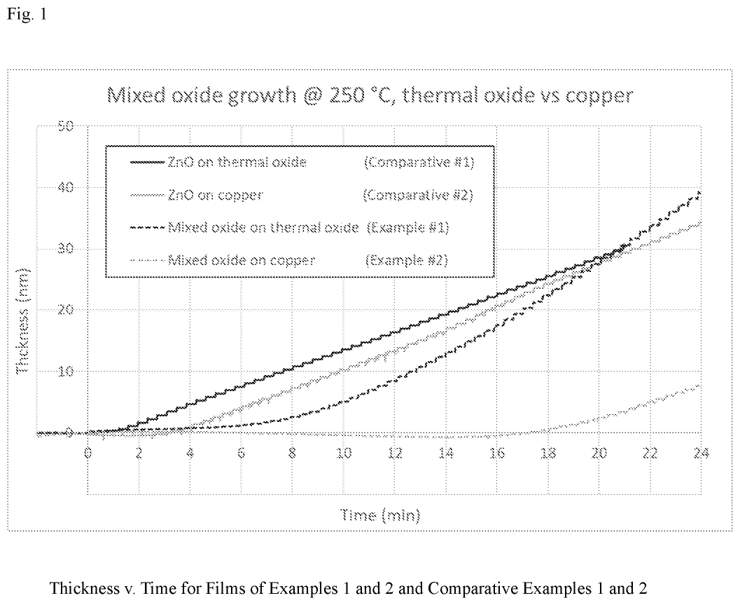

The following Table 1 compares the steps performed in Examples 1 and 2 and in Comparative Examples 1 and 2. The thickness v. time data for the films prepared in Examples 1 and 2 and Comparative Examples 1 and 2 are shown in FIG. 1. It is observed that on thermally-grown silicon dioxide, over 15 nm of a dielectric film with refractive index 1.48 can be grown under conditions that result in no film growth on copper. Utilizing similar conditions without the use of N-methyl-aza-2,2,4-trimethylsilacyclopentane results in little difference in growth on the same two substrates.

TABLE 1
Pulse Sequences for Examples 1 and
2 and Comparative Examples 1 and 2

| | |
|---|---|
| 1: | 60 s N₂ plasma pre-clean (2500 W) |
| 2: | 5.0 s N-methyl-aza-2,2,4-trimethylsilacyclopentane, 30 s purge |
| 3: | 0.1 diethylzinc, 5 s purge |
| 4: | 0.1 s water, 5 s purge |
| 5: | Repeat steps 2-4 seventy four additional times |

### Example 3

Silicon coated with 100 nm LPCVD silicon nitride was cleaned by sonication for five minutes in ethanol. A mixed oxide film comprised of zinc, silicon, oxygen, carbon and nitrogen was grown on the cleaned nitride film by exposing it to 60 seconds of 5% H₂/95% N₂ remote inductively coupled plasma (2500 W) at 225° C. and then subjecting it to an alternating pulse sequence of 0.5 seconds diethyl zinc, 5 second purge, 5.0 seconds N-methyl-aza-2,2,4-trimethylsilacyclopentane, 5 second purge, 2.0 seconds water, and 5 second purge, repeated 5 times, after which a 10 second pulse of the earlier plasma was employed to complete a super cycle. This supercycle was then repeated fifteen times. Film growth was immediate and stabilized at 32 angstroms per supercycle. The thickness of the film after the eighth supercycle was 14.4 nm and the refractive index 1.75.

### Example 4

Silicon coated with 100 nm LPVCD silicon nitride was cleaned by sonication for five minutes in ethanol. A mixed oxide film comprised of zinc, silicon, oxygen, carbon and nitrogen was grown on thermally-grown silicon dioxide by exposing it to 60 seconds of 5% H₂/95% N₂ remote inductively coupled plasma (2500 W) at 225° C. and then subjecting it to an alternating pulse sequence of 0.5 seconds diethyl zinc, 5 second purge, 5.0 seconds N-methyl-aza-2,2,4-trimethylsilacyclopentane, 5 second purge, 2.0 seconds water, and 5 second purge, repeated 5 times, after which a 10 second pulse of the earlier plasma was employed to complete a super cycle. This supercycle was then repeated fifteen times. Film growth was immediate and stabilized at 29 angstroms per supercycle. The thickness of the film after the eighth supercycle was 14.3 nm and the refractive index 1.75.

### Example 5

PVD copper on silicon was cleaned by sonication for five minutes in ethanol. A mixed oxide film was grown on the cleaned copper by exposing it to 60 seconds of 5% H₂/95% N₂ remote inductively coupled plasma (2500 W) at 225° C. and then subjecting it to an alternating pulse sequence of 0.5 seconds diethyl zinc, 5 second purge, 5.0 seconds N-methyl-aza-2,2,4-trimethylsilacyclopentane, 5 second purge, 2.0 seconds water, and 5 second purge, repeated 5 times, after which a 10 second pulse of the earlier plasma was employed to complete a super cycle. This supercycle was then repeated fifteen times. Initial film growth was observed during the ninth supercycle and had reached 26 angstroms per supercycle by the fifteenth supercycle.

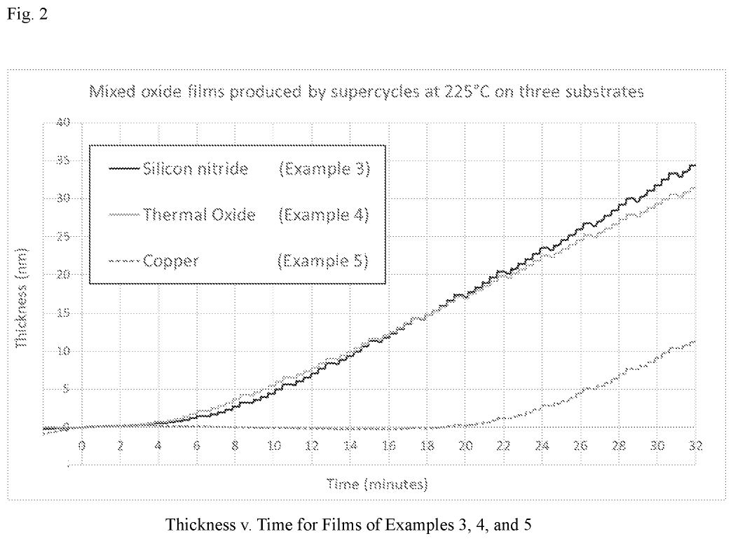

The following Table 2 summarizes the steps performed in Examples 3, 4, and 5; these examples differed only in the substrate employed. The thickness v. time data for the films prepared in Examples 3, 4, and 5 are shown in FIG. 2. It is observed that on both thermally-grown silicon dioxide and LPCVD silicon nitride surfaces, over 14 nm of a dielectric film with refractive index 1.75 can be grown under conditions that result in no film growth on copper.

TABLE 2
Pulse Sequences for Examples 3, 4, and 5

| | |
|---|---|
| 1: | 60 s 5% H₂ in N₂ plasma pre-clean (2500 W) |
| 2: | 0.5 s diethylzinc, 5 s purge |
| 3: | 5.0 s N-methyl-aza-2,2,4-trimethylsilacyclopentane, 5 s |
| | purge |
| 4: | 2.0 s water, 5 s purge |
| 5: | Repeat steps 2-4 four additional times |
| 6: | 10 s 5% H₂ in N₂ plasma (2500 W) |
| 7: | Repeat steps 2-6 fourteen additional times |

It will be appreciated by those skilled in the art that changes could be made to the embodiments described above without departing from the broad inventive concept thereof. It is understood, therefore, that this invention is not limited to the particular embodiments disclosed but it is intended to cover modifications within the spirit and scope of the present invention as defined by the appended claims.

We claim:

1. A method for forming a mixed oxide dielectric film on a patterned substrate, the method comprising:
(a) introducing a patterned substrate having metallic and non-metallic regions into a reaction zone of a deposition chamber and heating the reaction zone to about 175° C. to about 350° C.;
(b) exposing the patterned substrate to a pulse of a metal alkyl compound;
(c) purging the deposition chamber;
(d) exposing the patterned substrate to a pulse of a heteroatom silacyclic compound;
(e) purging the deposition chamber;
(f) exposing the patterned substrate to a pulse of water;
(g) purging the deposition chamber; and
(h) repeating steps (b) to (g) until a desired mixed oxide dielectric film thickness is achieved.

2. The method according to claim 1, further comprising performing a plasma treatment step prior to step (a).

3. The method according to claim 1, further comprising performing at least one plasma treatment step before or after any of steps (a) to (g).

4. The method according to claim 1, further comprising between steps (a) and (b) exposing the patterned substrate to a chemical compound that inhibits growth on some or all of the metallic regions and optionally removing the chemical compound after step (h).

5. The method according to claim 1, wherein the mixed oxide dielectric layer selectively forms on the non-metallic regions of the patterned substrate.

6. The method according to claim 1, wherein the metal alkyl compound is a Group 12 or Group 13 metal alkyl compound.

7. The method according to claim 6, wherein the metal alkyl compound is selected from diethylzinc, trimethyl aluminum, dimethylaluminum isopropoxide, dimethylzinc, trimethylgallium, triethylgallium, triethylaluminum, trimethylindium, dimethylcadmium, and dimethylmercury.

8. The method according to claim 1, wherein the heteroatom silacyclic compound is a cyclic azasilane having formula (1), a cyclic thiasilane having formula (2), or a cyclic tellurasilane having formula (3): 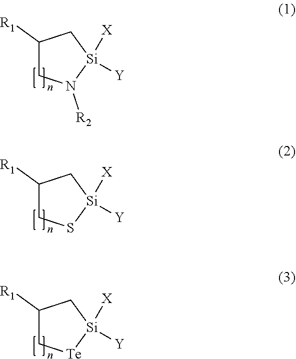
wherein R₁ is hydrogen or a linear, branched, or cyclic, optionally substituted, alkyl, aryl, alkynyl, alkenyl, alkoxy, silyl, or alkylamino group having 1 to about 12 carbon atoms, R₂ is a linear, branched, or cyclic, optionally substituted, alkyl, aryl, alkynyl, alkenyl, alkoxy, silyl, or alkylamino group having 1 to about 12 carbon atoms, n is an integer of 1 to about 4, and X and Y are each independently a linear, branched, or cyclic, optionally substituted, alkyl, aryl, alkynyl, alkenyl, alkoxy, silyl, or alkylamino group.

9. The method according to claim 8, wherein the heteroatom silacyclic compound is (N-methyl-aza-2,2,4-trimethyl silacyclopentane, N-(2-aminoethyl)-2,2,4-trimethyl-1-aza-silacyclopentane, N-n-butyl-aza-2,2-dimethoxysilacyclopentane, N-ethyl-2,2-dimethoxy-4-methyl-1-aza-2-silacyclopentane, (N,N-dimethylaminopropyl)-aza-2-methyl-2-methoxysilacyclopentane, (1-(3-triethoxysilyl)propyl)-2,2-diethoxy-1-aza-silacyclopentane, N-allyl-aza-2,2-dimethoxysilacyclopentane, N-t-butyl-aza-2,2-diemethoxysilacyclopentane, 2,2,4-trimethyl-1-thia-2-silacyclopentane, or 2,2,4-trimethyl-1-tellura-2-silacyclopentane.

10. The method according to claim 1, wherein the metallic region of the substrate comprises at least one of copper, cobalt, tungsten, ruthenium, and molybdenum.

11. The method according to claim 1, wherein the non-metallic region of the substrate comprises at least one of silicon, germanium, silicon-germanium alloy, silicon dioxide, silicon nitride, titanium nitride, tantalum nitride, silicon oxycarbide, silicon oxynitride, silicon carboxynitride, aluminum oxide, hafnium dioxide, titanium dioxide, and zinc oxide

12. The method according to claim 1, wherein the substrate is silicon dioxide, silicon nitride, or copper on silicon.

13. The method according to claim 1, wherein the pulse length of the heteroatom silacyclic compound in step (d) is about 0.1 to about 10 seconds, the pulse length of the metal alkyl compound in step (b) is about 0.1 to about 10 seconds, and the pulse length of the water in step (f) is about 0.1 to about 10 seconds.

14. The method according to claim 1, wherein the reaction zone in step (a) is heated to about 225° C. to about 275° C.

15. The method according to claim 1, wherein the mixed oxide dielectric film has a thickness of about 5 nm to about 50 nm.

16. The method according to claim 15, wherein the mixed oxide dielectric film has a thickness of about 5 nm to about 15 nm.

17. A method for forming a mixed oxide dielectric film on a patterned substrate, the method comprising:
(a) introducing a patterned substrate having metallic and non-metallic regions into a reaction zone of a deposition chamber and heating the reaction zone to about 175° C. to about 350° C.;
(b) exposing the patterned substrate to a pulse of a metal alkyl compound;
(c) purging the deposition chamber;
(d) exposing the patterned substrate to a pulse of a heteroatom silacyclic compound;
(e) purging the deposition chamber;
(f) exposing the substrate to a pulse of water;
(g) purging the deposition chamber; and
(h) repeating steps (b) to (g) at least one time;
(i) performing a plasma treatment step; and
(j) repeating steps (b) to (i) until a desired mixed oxide dielectric film thickness is achieved.

18. The method according to claim 17, further comprising performing a plasma treatment step prior to step (a).

19. The method according to claim 17, further comprising performing at least one plasma treatment step before or after any of steps (a) to (i).

20. The method according to claim 17, further comprising between steps (a) and (b) exposing the patterned substrate to a chemical compound that inhibits growth on some or all of the metallic regions and optionally removing the chemical compound after step (j).

21. The method according to claim 17, wherein the mixed oxide dielectric layer selectively forms on the non-metallic regions of the patterned substrate.

22. The method according to claim 17, wherein the metal alkyl compound is a Group 12 or Group 13 metal alkyl compound.

23. The method according to claim 22, wherein the metal alkyl compound is selected from diethylzinc, trimethyl aluminum, dimethylaluminum isopropoxide, dimethylzinc, trimethylgallium, triethylgallium, triethylaluminum, trimethylindium, dimethylcadmium, and dimethylmercury.

24. The method according to claim 17, wherein the heteroatom silacyclic compound is a cyclic azasilane having formula (1), a cyclic thiasilane having formula (2), or a cyclic tellurasilane having formula (3): 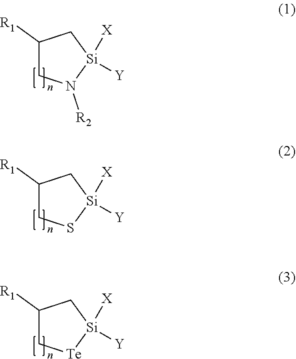
wherein R₁ is hydrogen or a linear, branched, or cyclic, optionally substituted, alkyl, aryl, alkynyl, alkenyl, alkoxy, silyl, or alkylamino group having 1 to about 12 carbon atoms, R₂ is a linear, branched, or cyclic, optionally substituted, alkyl, aryl, alkynyl, alkenyl, alkoxy, silyl, or alkylamino group having 1 to about 12 carbon atoms, n is an integer of 1 to about 4, and X and Y are each independently a linear, branched, or cyclic, optionally substituted, alkyl, aryl, alkynyl, alkenyl, alkoxy, silyl, or alkylamino group.

25. The method according to claim 24, wherein the heteroatom silacyclic compound is (N-methyl-aza-2,2,4-trimethylsilacyclopentane, N-(2-aminoethyl)-2,2,4-trim ethyl-1-aza-silacyclopentane, N-n-butyl-aza-2,2-dimethoxysilacyclopentane, N-ethyl-2,2-dim ethoxy-4-methyl-1-aza-2-silacyclopentane, (N,N-dimethylaminopropyl)-aza-2-methyl-2-m ethoxy silacyclopentane, (1-(3-triethoxysilyl)propyl)-2,2-diethoxy-1-aza-silacyclopentane, N-allyl-aza-2,2-dimethoxysilacyclopentane, N-t-butyl-aza-2,2-diemethoxysilacyclopentane, 2,2,4-trim ethyl-1-thia-2-silacyclopentane, or 2,2,4-trim ethyl-1-tellura-2-silacyclopentane.

26. The method according to claim 17, wherein the metallic region of the substrate comprises at least one of copper, cobalt, tungsten, ruthenium, and molybdenum.

27. The method according to claim 17, wherein the non-metallic region of the substrate comprises at least one of silicon, germanium, silicon-germanium alloy, silicon dioxide, silicon nitride, titanium nitride, tantalum nitride, silicon oxycarbide, silicon oxynitride, silicon carboxynitride, aluminum oxide, hafnium dioxide, titanium dioxide, and zinc oxide

28. The method according to claim 17, wherein the substrate is silicon dioxide, silicon nitride, or copper on silicon.

29. The method according to claim 17, wherein the pulse length of the heteroatom silacyclic compound in step (d) is about 0.1 to about 10 seconds, the pulse length of the metal alkyl compound in step (b) is about 0.1 to about 10 seconds, and the pulse length of the water in step (f) is about 0.1 to about 10 seconds.

30. The method according to claim 17, wherein the reaction zone in step (a) is heated to about 225° C. to about 275° C.

31. The method according to claim 17, wherein the mixed oxide dielectric film has a thickness of about 5 nm to about 50 nm.

32. The method according to claim 31, wherein the mixed oxide dielectric film has a thickness of about 5 nm to about 15 nm.
